(19) United States
(12) Patent Application Publication
(10) Pub. No.: US 2026/0223493 A1
(43) Pub. Date: Jul. 30, 2026

(54) LIGHT-EMITTING ARRAY SUBSTRATE, LIGHT-EMITTING ARRAY CHIP AND MANUFACTURING METHOD

(71) Applicant: YONGJIANG LABORATORY, Ningbo (CN)

(72) Inventors: Liang ZHANG, Ningbo (CN); Runan ZHANG, Ningbo (CN); Shulin CHEN, Ningbo (CN); Min LIU, Ningbo (CN); Haifang LU, Ningbo (CN); Ze YUAN, Ningbo (CN)

(21) Appl. No.: 19/572,799

(22) Filed: Mar. 19, 2026

Related U.S. Application Data
(63) Continuation of application No. PCT/CN2024/117556, filed on Sep. 6, 2024.

(30) Foreign Application Priority Data
Sep. 26, 2023 (CN) 202311260412.4

(51) Int. Cl. H10H 20/831; H10H 20/01; H10H 20/832; H10H 20/857; H10H 29/01

(52) U.S. Cl. CPC H10H 20/8316; H10H 20/017; H10H 20/032; H10H 20/0364; H10H 20/832; H10H 20/857; H10H 29/012

(57) ABSTRACT

Provided are a light-emitting array substrate, a light-emitting array chip, and a manufacturing method. The light-emitting array substrate includes a light-emitting diode unit and an electrode unit. The light-emitting diode unit is provided with a first conductivity-type electrode on its first side and a second conductivity-type electrode on its second side. The first conductivity-type electrode and the second conductivity-type electrode have an independent potential connection relationship. The electrode unit is provided with a second conductivity-type electrode on its first side. The first side of the light-emitting diode unit and the first side of the electrode unit are on a same side. The second conductivity-type electrode of the electrode unit is connected to the second conductivity-type electrode of the light-emitting diode unit to form a second conductivity-type conductive channel.

### CROSS-REFERENCE TO RELATED APPLICATION

This application is a continuation of International Patent Application No. PCT/CN2024/117556, filed on September 6, 2024, which is based on and claims priority to Chinese Patent Application No. 202311260412.4, filed on September 26, 2023, both of which are incorporated herein by reference in their entireties.

### FIELD

The present disclosure relates to the field of display technologies, and particularly, to a light-emitting array substrate, a light-emitting array chip, and a manufacturing method.

### BACKGROUND

A Micro Light Emitting Diode Display (Micro-LED) is widely used due to its performance advantages such as high brightness, low power consumption, fast response time, high contrast, high resolution, and color saturation. For example, monolithic integration of the Micro-LED with a Complementary Metal Oxide Semiconductor (CMOS) has emerged as an ideal solution in the field of Augmented Reality (AR). With the increasing demand for high pixels per inch (PPI) in displays, smaller pixel pitch is required. The Micro-LED and the CMOS typically employ a vertical injection configuration to enable independent circuit control of each individual pixel in a Micro-LED array by the CMOS. In such a vertical injection configuration, P electrodes of each Micro-LED device are typically connected to the CMOS, and N electrodes of each Micro-LED device are short-circuited and connected to the CMOS together, which is referred to as a common N-electrode connection. In the related art, two types of the common N-electrode connection are as follows.

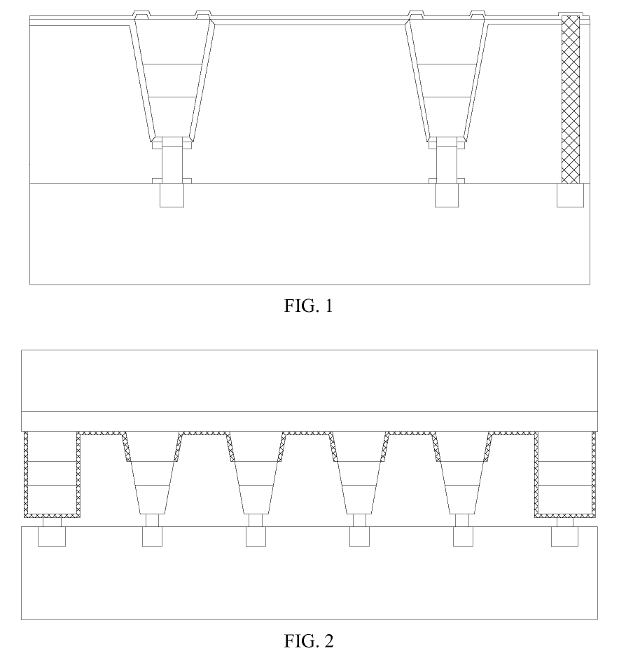

Referring to FIG. 1, the Micro-LED array is designed with a metallic via extending through the Micro-LED array. The metallic via has an end electrically connected to N-electrode metal and another end electrically connected to the CMOS. However, such metallic vias tend to undergo incomplete filling when fabricated adopting a conventional deposition process. When electroplating is adopted for the filling, it requires pre-deposition of a seed layer before the electroplating as well as Chemical Mechanical Polishing (CMP) and seed layer surface removal after the electroplating. Furthermore, the electroplating process itself requires a wet chemical procedure, which is limited by equipment and environment factors.

Referring to FIG. 2, the N-electrode metal extends laterally toward the CMOS side to achieve an electrical connection with the CMOS. However, the N-electrode metal has a large coverage area, leading to unnecessary light absorption, thus reducing light emission efficiency of the device. Therefore, the manufacturing process of the Micro LED array is complex, and its light emission effect is suboptimal.

### SUMMARY

The present disclosure aims to solve at least one of the technical problems in the related art. To this end, the present disclosure provides a light-emitting array substrate, a light-emitting array chip, and a manufacturing method.

In a first aspect, the present disclosure provides a light-emitting array substrate. The light-emitting array substrate includes a light-emitting diode unit and an electrode unit. The light-emitting diode unit is provided with a first conductivity-type electrode on a first side of the light-emitting diode unit and a second conductivity-type electrode on a second side of the light-emitting diode unit. The first conductivity-type electrode and the second conductivity-type electrode have an independent potential connection relationship. The electrode unit is provided with a second conductivity-type electrode on a first side of the electrode unit. The first side of the light-emitting diode unit and the first side of the electrode unit are on a same side. The second conductivity-type electrode of the electrode unit is connected to the second conductivity-type electrode on the second side of the light-emitting diode unit to form a second conductivity-type conductive channel.

According to an embodiment of the present disclosure, the second conductivity-type electrode of the electrode unit and the first conductivity-type electrode of the light-emitting diode unit are manufactured using a same process.

According to an embodiment of the present disclosure, each of the second conductivity-type electrode of the electrode unit and the first conductivity-type electrode of the light-emitting diode unit is made of tin, gold, nickel, palladium, copper or an alloy including at least two of tin, gold, nickel, palladium, or copper; and the second conductivity-type electrode of the light-emitting diode unit is made of Ti/Al or Ti/Au.

According to an embodiment of the present disclosure, a mesa of the electrode unit and a mesa of the light-emitting diode unit are at least partially formed using a same process.

According to an embodiment of the present disclosure, the light-emitting array substrate further includes a conductive layer disposed on the second side of the light-emitting diode unit. The conductive layer is connected to the second conductivity-type electrode of the light-emitting diode unit and the second conductivity-type electrode of the electrode unit to form the conductive channel.

According to an embodiment of the present disclosure, the electrode unit has an opening extending through the mesa of the electrode unit. The opening is configured to expose the second conductivity-type electrode of the electrode unit toward a side where the conductive layer is located, and the conductive layer is connected to the second conductivity-type electrode of the electrode unit through the opening.

According to an embodiment of the present disclosure, a fillingstructure is formed in the opening and configured to cover a part of the conductive layer located in the opening and to achieve planarization.

According to an embodiment of the present disclosure, the fillingstructure is made of a metallic material.

According to an embodiment of the present disclosure, a connection region between the light-emitting diode unit and the electrode unit has an opening. The second conductivity-type electrode of the electrode unit extends to the connection region along an outer side wall of the mesa of the electrode unit and is exposed through the opening.

According to an embodiment of the present disclosure, a part of a mesa of the light-emitting diode unit close to the second side is connected to a part of a mesa of the electrode unit close to the second side.

According to an embodiment of the present disclosure, the light-emitting array substrate further includes a plurality of light-emitting diode units. A conductive layer is in contact with a second conductivity-type electrode corresponding to each of the light-emitting diode units.

According to an embodiment of the present disclosure, the light-emitting array substrate further includes a plurality of electrode units. The conductive layer is in contact with a first conductivity-type electrode corresponding to each of the electrode units.

In a second aspect, the present disclosure provides a light-emitting array chip. The light-emitting array chip includes a drive backplane and the light-emitting array substrate according to the above-mentioned embodiments. The light-emitting array substrate is bonded to the drive backplane.

In a third aspect, the present disclosure provides a method for manufacturing a light-emitting array substrate. The method includes:

providing a substrate, and forming a light-emitting epitaxial layer on the substrate, in which the light-emitting epitaxial layer has a first side and a second side opposite to the first side, and the second side is a side where the substrate is located;

etching the light-emitting epitaxial layer at the first side to form a light-emitting diode unit and an electrode unit;

forming, on the first side, a first conductivity-type electrode on the light-emitting diode unit and a second conductivity-type electrode on the electrode unit;

removing the substrate;

forming a first opening on the light-emitting epitaxial layer, in which the first opening is configured to expose the second conductivity-type electrode of the electrode unit toward the second side of the light-emitting epitaxial layer;

forming, on the second side, a second conductivity-type electrode on the light-emitting diode unit; and

forming a conductive layer on the second side, in which the conductive layer is contact-connected to the second conductivity-type electrode of the light-emitting diode unit and to the second conductivity-type electrode of the electrode unit that is exposed through the first opening.

According to an embodiment of the present disclosure, said forming the first conductivity-type electrode on the light-emitting diode unit and the second conductivity-type electrode on the electrode unit includes:

forming a passivation layer on an upper surface of each of the light-emitting diode unit and the electrode unit;

etching a part of the passivation layer on a top of each of the light-emitting diode unit and the electrode unit to form a second opening configured to expose the light-emitting diode unit and a second opening configured to expose the electrode unit; and

simultaneously forming, using a same photolithography process, the first conductivity-type electrode in the second opening of the light-emitting diode unit and the second conductivity-type electrode in the second opening of the electrode unit.

According to an embodiment of the present disclosure, the second conductivity-type electrode of the electrode unit is located at the top of the electrode unit; and said forming the first opening on the light-emitting epitaxial layer includes:

etching, on the second side of the light-emitting epitaxial layer, the electrode unit to form the first opening configured to expose the second conductivity-type electrode of the electrode unit.

According to an embodiment of the present disclosure, the second conductivity-type electrode of the electrode unit extends to a bottom of the electrode unit from the top of the electrode unit along a side wall of the electrode unit, and extends to a connection region between the electrode unit and the light-emitting diode unit adjacent to the electrode unit; and said forming the first opening on the light-emitting epitaxial layer includes:

etching, on the second side of the light-emitting epitaxial layer, the connection region to form the first opening configured to expose the second conductivity-type electrode of the electrode unit.

According to an embodiment of the present disclosure, the method further includes, prior to said removing the substrate:

forming a planarization layer on the first side of the light-emitting epitaxial layer, in which the planarization layer is configured to cover the light-emitting diode unit and the electrode unit;

etching a part of the planarization layer above the first conductivity-type electrode of the light-emitting diode unit and the second conductivity-type electrode of the electrode unit to form third openings configured to expose the first conductivity-type electrode, and the second conductivity-type electrode of the electrode unit;

forming conductive connectors in the third openings; and

bonding the conductive connectors to a drive backplane.

According to an embodiment of the present disclosure, the conductive connectors are made of tin, gold, nickel, palladium, copper, or an alloy including at least two of tin, gold, nickel, palladium, or copper.

According to an embodiment of the present disclosure, the method further includes, subsequent to said removing the substrate:

thinning the light-emitting epitaxial layer at the second side.

According to an embodiment of the present disclosure, a passivation layer is formed on a surface of each of the light-emitting diode unit and the electrode unit on the first side and exposed on the second side of the thinned light-emitting epitaxial layer.

Additional aspects and advantages of the embodiments of present disclosure will be provided at least in part in the following description, or will become apparent in part from the following description, or can be learned from the practice of the embodiments of the present disclosure.

### BRIEF DESCRIPTION OF THEDRAWINGS

These and other aspects and advantages of embodiments of the present disclosure will become apparent and more readily appreciated from the following descriptions made with reference to the accompanying drawings.

FIG. 1 is a first schematic structural diagram of a light-emitting array substrate in the related art.

FIG. 2 is a second schematic structural diagram of a light-emitting array substrate in the related art.

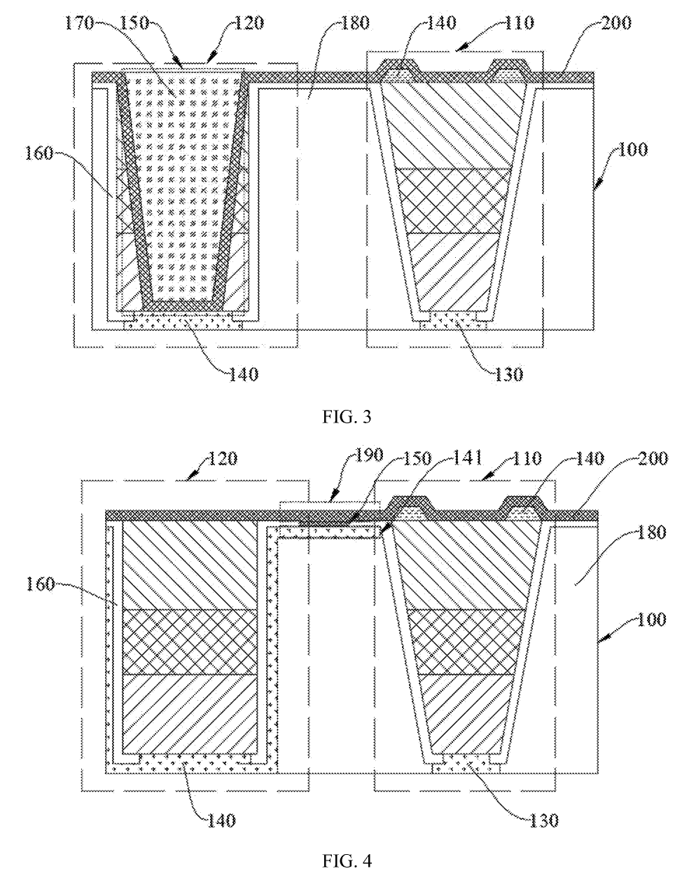

FIG. 3 is a first schematic structural diagram of a light-emitting array substrate according to an embodiment of the present disclosure.

FIG. 4 is a second schematic structural diagram of a light-emitting array substrate according to an embodiment of the present disclosure.

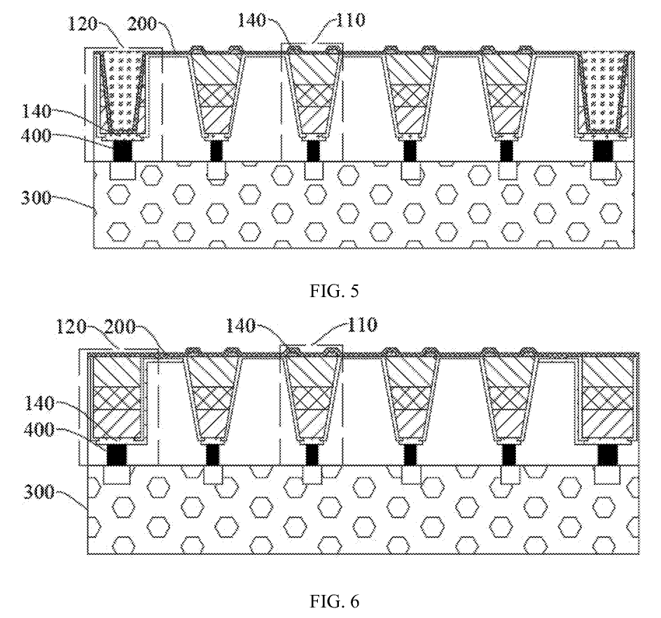

FIG. 5 is a first schematic structural diagram of a light-emitting array chip according to an embodiment of the present disclosure.

FIG. 6 is a second schematic structural diagram of a light-emitting array chip according to an embodiment of the present disclosure.

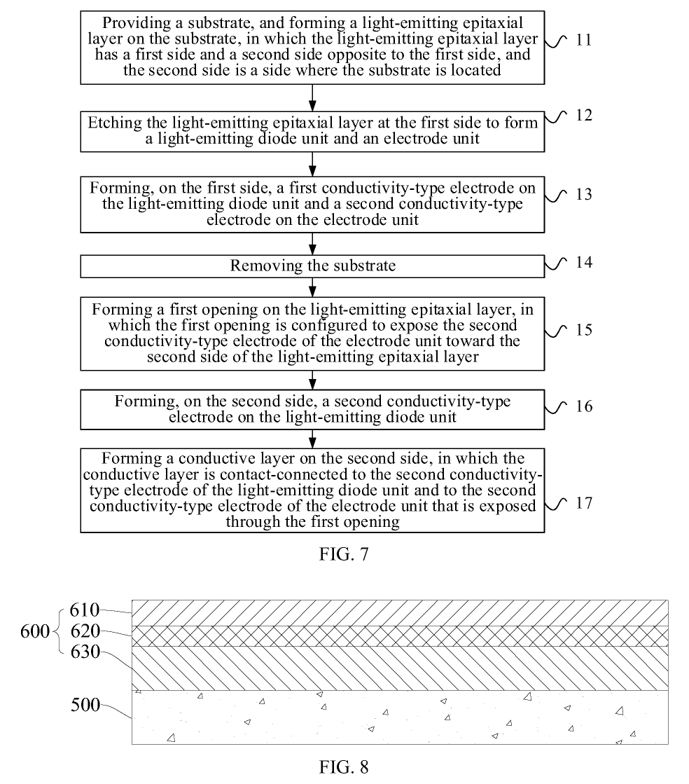

FIG. 7 is a first schematic flowchart of a method for manufacturing a light-emitting array substrate according to an embodiment of the present disclosure.

FIG. 8 is a first schematic structural diagram of a stage in a manufacturing method according to an embodiment of the present disclosure.

FIG. 9 is a second schematic structural diagram of a stage in a manufacturing method according to an embodiment of the present disclosure.

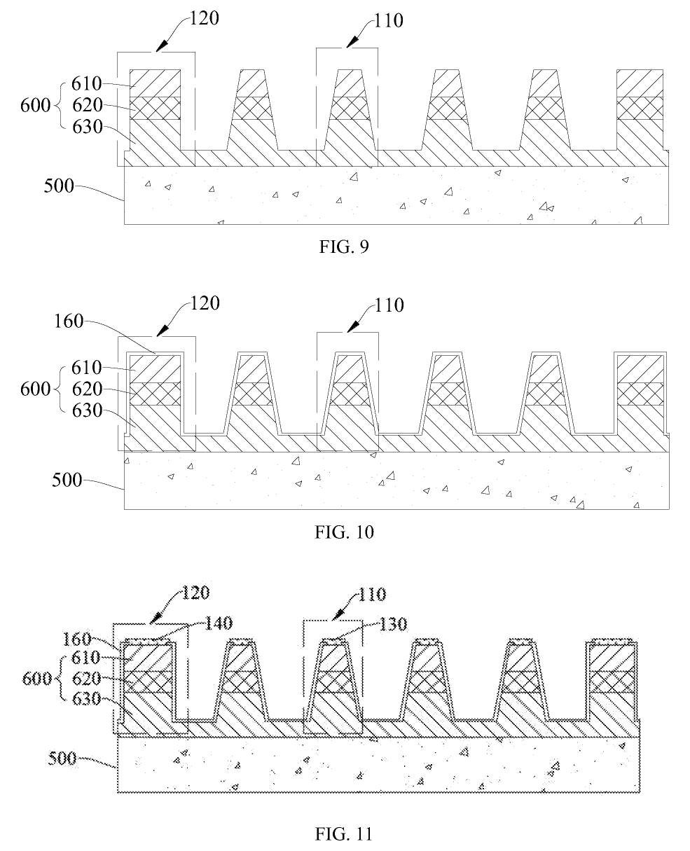

FIG. 10 is a third schematic structural diagram of a stage in a manufacturing method according to an embodiment of the present disclosure.

FIG. 11 is a fourth schematic structural diagram of a stage in a manufacturing method according to an embodiment of the present disclosure.

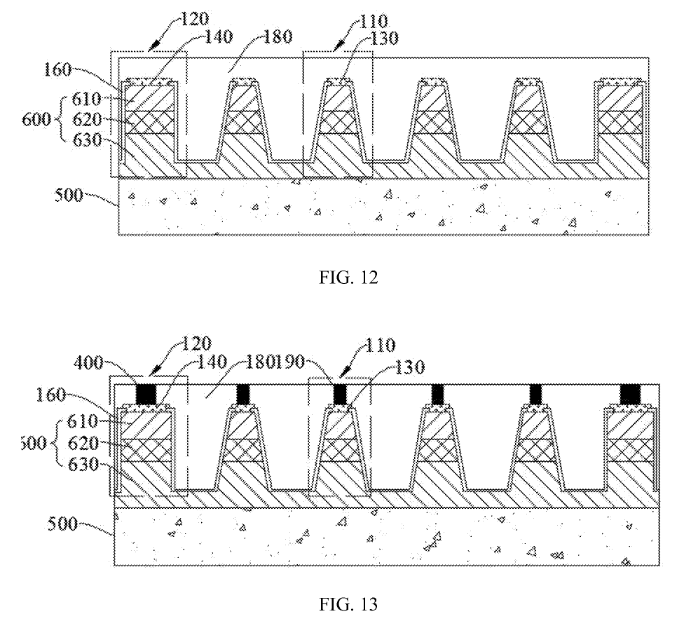

FIG. 12 is a fifth schematic structural diagram of a stage in a manufacturing method according to an embodiment of the present disclosure.

FIG. 13 is a sixth schematic structural diagram of a stage in a manufacturing method according to an embodiment of the present disclosure.

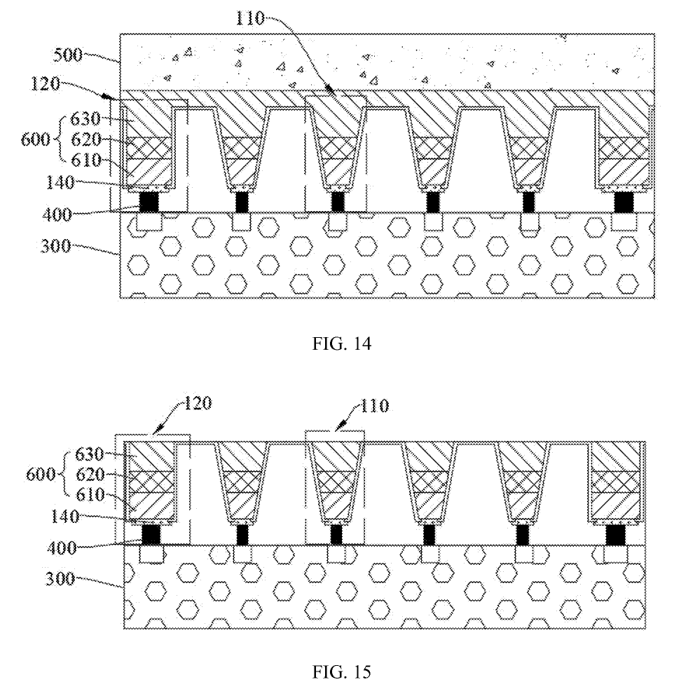

FIG. 14 is a seventh schematic structural diagram of a stage in a manufacturing method according to an embodiment of the present disclosure.

FIG. 15 is an eighth schematic structural diagram of a stage in a manufacturing method according to an embodiment of the present disclosure.

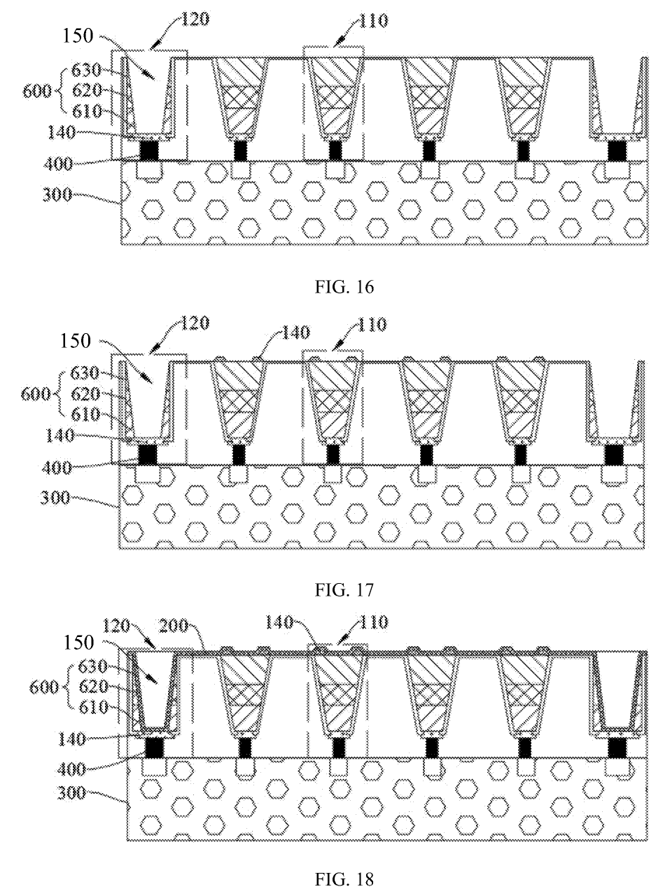

FIG. 16 is a ninth schematic structural diagram of a stage in a manufacturing method according to an embodiment of the present disclosure.

FIG. 17 is a tenth schematic structural diagram of a stage in a manufacturing method according to an embodiment of the present disclosure.

FIG. 18 is an eleventh schematic structural diagram of a stage in a manufacturing method according to an embodiment of the present disclosure.

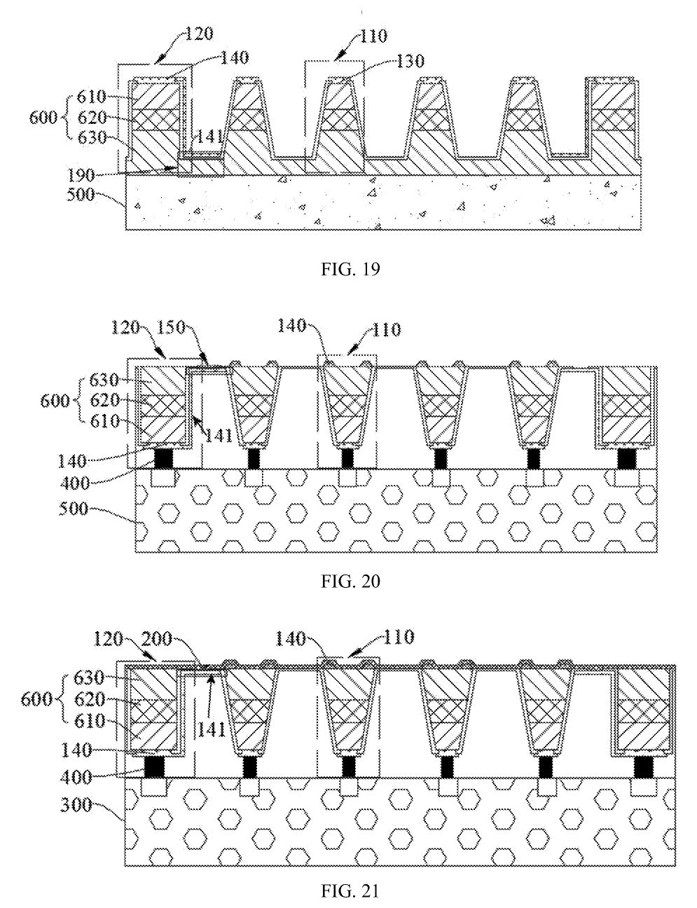

FIG. 19 is a twelfth schematic structural diagram of a stage in a manufacturing method according to an embodiment of the present disclosure.

FIG. 20 is a thirteenth schematic structural diagram of a stage in a manufacturing method according to an embodiment of the present disclosure.

FIG. 21 is a fourteenth schematic structural diagram of a stage in a manufacturing method according to an embodiment of the present disclosure.

### Reference numerals:

light-emitting layer 100, light-emitting diode unit 110, electrode unit 120, first conductivity-type electrode 130, extending portion 141, second conductivity-type electrode 140, first opening 150, passivation layer 160, fillingstructure 170, planarization layer 180, connection region 190, conductive layer 200, drive backplane 300, conductive connector 400, substrate 500, light-emitting epitaxial layer 600, first doped semiconductor 610, active layer 620, second doped semiconductor 630.

### DETAILED DESCRIPTION OF THE EMBODIMENTS

The embodiments of the present disclosure will be described in detail below with reference to examples thereof as illustrated in the accompanying drawings. In the accompanying drawings, sizes of layers, regions, elements and their relative sizes may be exaggerated for clarity. Throughout the description, same or similar elements, or elements having same or similar functions, are denoted by same or similar reference numerals. The embodiments described below with reference to the drawings are illustrative only, and are intended to explain rather than limit the present disclosure.

It should be understood that when an element or layer is referred to as being “on,” “adjacent to,” “connected to” or “coupled to” other elements or layers, it may be directly on, adjacent to, connected to or coupled to other elements or layers, or there may be intervening elements or layers. On the contrary, when an element is referred to as being “directly on,” “directly adjacent to,” “directly connected to” or “directly coupled to” elements or layers, there are no intervening elements or layers. It should be understood that although terms “first,” “second,” “third,” etc. may be used to describe various elements, components, regions, layers and/or parts, these elements, components, regions, layers and/or parts should not be limited by these terms. These terms are only used to distinguish one element, component, region, layer or part from another element, component, region, layer or part. Therefore, a first element, component, region, layer or part discussed below may be represented as a second element, component, region, layer or part, without departing from the teachings of the present disclosure. When the second element, component, region, layer or part is discussed, it does not mean that the first element, component, region, layer or part necessarily exists in the present disclosure.

In the description of this specification, descriptions with reference to the terms “an embodiment”, “some embodiments”, “an exemplary embodiment”, “an example”, “a specific example”, or “some examples” etc., mean that specific features, structure, materials or characteristics described in conjunction with the embodiment or example are included in at least one embodiment or example of the present disclosure. In this specification, the schematic representations of the above terms do not necessarily refer to the same embodiment or example. Moreover, the described specific features, structures, materials or characteristics may be combined in any one or more embodiments or examples in a suitable manner.

Referring to FIGS. 3 and 4, an embodiment of the present disclosure provides a light-emitting array substrate. In this embodiment, the light-emitting array substrate includes a light-emitting diode unit 110 and an electrode unit 120. The light-emitting diode unit 110 is provided with a first conductivity-type electrode 130 on a first side of the light-emitting diode unit 110 and a second conductivity-type electrode 140 on a second side of the light-emitting diode unit 110. The first conductivity-type electrode 130 and the second conductivity-type electrode 140 have an independent potential connection relationship. The electrode unit 120 is provided with a second conductivity-type electrode 140 on a first side of the electrode unit 120. The first side of the light-emitting diode unit 110 and the first side of the electrode unit 120 are on a same side. The second conductivity-type electrode 140 of the electrode unit 120 is connected to the second conductivity-type electrode 140 of the light-emitting diode unit 110 to form a second conductivity-type conductive channel.

It should be noted that shapes of the light-emitting diode unit 110 and the electrode unit 120 shown in the accompanying drawings of the present disclosure are only distinguished for ease of illustration. In practice, the light-emitting diode unit 110 and the electrode unit 120 in the light-emitting array substrate may have a same shape.

It can be understood that the first conductivity-type electrode 130 of the light-emitting diode unit 110 may be a P-type electrode, and the second conductivity-type electrode 140 of the light-emitting diode unit 110 may be an N-type electrode; or the first conductivity-type electrode 130 of the light-emitting diode unit 110 may be an N-type electrode, and the second conductivity-type electrode 140 of the light-emitting diode unit 110 may be a P-type electrode. Since the light-emitting array substrate may be connected to a drive in a vertical injection configuration during use, for ease of connection, a connection position between the P-type electrode of the light-emitting diode unit 110 of the light-emitting array substrate and a drive backplane 300 and a connection position between the N-type electrode of the light-emitting diode unit 110 of the light-emitting array substrate and the drive backplane 300 need to be disposed on a same side.

The light-emitting diode unit 110 is electrically connected to a drive circuit through the first conductivity-type electrode 130 to more conveniently control an incoming current. The second conductivity-type electrode 140 of the light-emitting diode unit 110 is also used to make an electrical connection with the drive circuit so as to more easily control an outgoing current.

In this embodiment, the second conductivity-type electrode 140 of the electrode unit 120 is disposed on the first side of the light-emitting diode unit 110 and is configured to be electrically connected to the second conductivity-type electrode 140 on the second side of the light-emitting diode unit 110, enabling the second conductivity-type electrode 140 on the second side of the light-emitting diode unit 110 to be electrically connected to the side where the first conductivity-type electrode of the light-emitting diode unit 110 is located.

A drive current is provided on the first side of the light-emitting diode unit 110. The drive current flows into the light-emitting diode unit 110 from the first conductivity-type electrode 130 of the light-emitting diode unit 110, then flows out of the second conductivity-type electrode 140 of the light-emitting diode unit 110, then flows towards the second conductivity-type electrode 140 of the electrode unit 120, and finally returns to the first side of the light-emitting diode unit 110.

According to the light-emitting array substrate of the present disclosure, by forming the electrode unit 120 and utilizing the connection between the second conductivity-type electrode 140 on the first side of the electrode unit 120 and the second conductivity-type electrode 140 on the second side of the light-emitting diode unit 110, the current inflow and outflow of the light-emitting array substrate are located on the same side, eliminating the need for additional metallic vias, resulting in a simple structure and no impact on light emission efficiency.

In some embodiments, the second conductivity-type electrode 140 of the electrode unit 120 and the first conductivity-type electrode 130 of the light-emitting diode unit 110 are manufactured using a same process.

Since the second conductivity-type electrode 140 of the electrode unit 120 and the first conductivity-type electrode 130 of the light-emitting diode unit 110 are located on the same side, both of them can be manufactured simultaneously, thus simplifying the process.

In some embodiments, the first conductivity-type electrode 130 corresponding to the light-emitting diode unit 110 may be a P-type electrode, and the second conductivity-type electrode 140 corresponding to the light-emitting diode unit 110 may be an N-type electrode. Therefore, although the second conductivity-type electrode 140 corresponding to the electrode unit 120 is made of the same material (i.e., a P-type material) as the first conductivity-type electrode 130 corresponding to the light-emitting diode unit 110, the second conductivity-type electrode 140 corresponding to the electrode unit 120 is reused as an N-electrode connection.

In some other embodiments, the first conductivity-type electrode 130 corresponding to the light-emitting diode unit 110 may be an N-type electrode, and the second conductivity-type electrode 140 may be a P-type electrode. In this case, the second conductivity-type electrode 140 of the electrode unit 120 that is made of an N-type material is reused as a P-type electrode connection.

According to the light-emitting array substrate of the present disclosure, the first conductivity-type electrode 130 of the light-emitting diode unit 110 and the second conductivity-type electrode 140 of the electrode unit 120 are manufactured using the same process, simplifying the process and reducing costs.

In some embodiments, the second conductivity-type electrode 140 of the electrode unit 120 and the first conductivity-type electrode 130 of the light-emitting diode unit 110 may be made of tin, gold, nickel, palladium, copper, or an alloy including at least two of tin, gold, nickel, palladium, or copper. The alloy may be, for example, a gold-nickel alloy or a copper-nickel alloy. The second conductivity-type electrode 140 of the light-emitting diode unit 110 is made of Ti/Al or Ti/Au.

In some embodiments, a mesa of the electrode unit 120 and a mesa of the light-emitting diode unit 110 are at least partially formed using a same process.

In this embodiment, the mesa of the electrode unit 120 and the mesa of the light-emitting diode unit 110 may be formed by depositing a same material and etching the deposited material. The electrode unit 120 and the light-emitting diode unit 110 are manufactured using the same process. By repurposing part of a semiconductor material used for light emission into the electrode unit 120, manufacturing steps can be reduced, and the process can be simplified.

In some embodiments, the light-emitting array substrate further includes a conductive layer 200 disposed on the second side of the light-emitting diode unit 110. The conductive layer 200 is connected to the second conductivity-type electrode 140 of the light-emitting diode unit 110 and the second conductivity-type electrode 140 of the electrode unit 120 to form the conductive channel.

In some embodiments, the conductive layer 200 may be an Indium Tin Oxide (ITO) semiconductor transparent conductive film. The transparent nature of the conductive layer 200 can facilitate light emission from the light-emitting array substrate.

In some embodiments, the electrode unit 120 is formed by reusing a process and a structure of the lighting emitting diode unit 110. By way of example, in some embodiments, a mesa of the light-emitting diode unit 110 in the light-emitting array substrate is used to form the electrode unit 120, and/or the second conductivity-type electrode 140 of the electrode unit 120 and the first conductivity-type electrode 130 of the light-emitting diode unit 110 are manufactured using a same process (for example, a same photolithography process).

By reusing the process and structure of the light-emitting diode unit 110 to form the electrode unit 120, the manufacturing process of the light-emitting array substrate is simplified and costs are reduced.

With continued reference to FIG. 3, in some embodiments, the electrode unit 120 has a first opening 150 extending through the mesa of the electrode unit 120. The first opening 150 is configured to expose the second conductivity-type electrode 140 of the electrode unit 120 toward the side where the conductive layer 200 is located, and the conductive layer 200 is connected to the second conductivity-type electrode 140 of the electrode unit 120 through the first opening 150.

In this embodiment, the first opening 150 may be formed by etching the electrode unit 120. Prior to the etching of the electrode unit 120, the electrode unit 120 may have a same semiconductor stack structure as the light-emitting diode unit 110, that is, both the electrode unit 120 and the light-emitting diode unit 110 include a stacked P-type semiconductor layer, an active layer, and an N-type semiconductor layer. The P-type semiconductor layer may be made of P-type gallium nitride, and the N-type semiconductor layer may be made of N-type gallium nitride. Of course, other types of materials may also be used, and this embodiment does not impose any limitation thereon.

In some embodiments, during the etching of the electrode unit 120, the original semiconductor stack structure may alternatively be completely etched. That is, in the light-emitting array substrate shown in FIG. 3, no P-type semiconductor layer, active layer, and N-type semiconductor layer are retained on two sides of the first opening 150 of the electrode unit 120.

In some embodiments, the first conductivity-type electrode 130 of the light-emitting diode unit 110 may be a P-type electrode, and the second conductivity-type electrode 140 of the light-emitting diode unit 110 may be an N-type electrode. The N-type electrode is connected to a side where the P-type electrode is located through the conductive layer 200. The light-emitting diode unit 110 sequentially includes the P-type semiconductor layer, the active layer, and the N-type semiconductor layer from the side where the P-type electrode is located to a side where the N-type electrode is located.

In this embodiment, the second conductivity-type electrode 140 on the first side of the electrode unit 120 is still made of the P-electrode material. Since the second conductivity-type electrode 140 of the electrode unit 120 is connected to the N-type electrode of the light-emitting diode unit 110 through the conductive layer 200, using a P-type electrode material to realize the N-electrode connection does not affect its electrical conductivity. However, since the second conductivity-type electrode 140 on the first side of the electrode unit 120 and the first conductivity-type electrode 130 on the first side of the light-emitting diode unit 110 are made of the same polarity material, they can be manufactured through the same process, thereby simplifying the process.

In some other embodiments, the first conductivity-type electrode 130 of the light-emitting diode unit 110 may be an N-type electrode, and the second conductivity-type electrode 140 of the light-emitting diode unit 110 may be a P-type electrode. The P-type electrode is connected, via the conductive layer 200, to a side where the N-type electrode is located. The light-emitting diode unit 110 sequentially includes the N-type semiconductor layer, the active layer, and the P-type semiconductor layer from the side where the N-type electrode is located to a side where the P-type electrode is located.

Similarly, in this embodiment, the second conductivity-type electrode 140 of the electrode unit 120 is also made of the N-type electrode material. Therefore, both the second conductivity-type electrode 140 of the electrode unit 120 and the first conductivity-type electrode 130 of the light-emitting diode unit 110 can be manufactured using the same process, thereby simplifying the process and without affecting conductivity of the conductive channel.

It can be understood that in the light-emitting array substrate shown in FIG. 3, the light-emitting diode unit 110 and the electrode unit 120 are independent units, and the semiconductor layers of the mesas of the light-emitting diode unit 110 and the electrode unit 120 that are close to the second side are not connected to each other.

In some embodiments, a part of the mesa of the light-emitting diode unit 110 close to the second side is connected to a part of the mesa of the electrode unit 120 close to the second side. For example, in a direction toward the second side, a bottom of each of the mesa of the light-emitting diode unit 110 and the mesa of the electrode unit 120 is a P-type semiconductor layer, and the P-type semiconductor layers at the bottom of each of the mesa of the light-emitting diode unit 110 and the mesa of the electrode unit 120 are connected into a continuous layer. Alternatively, in the direction toward the second side, the bottom of each of the mesa of the light-emitting diode unit 110 and the mesa of the electrode unit 120 is an N-type semiconductor layer, the N-type semiconductor layers at the bottom of each of the mesa of the light-emitting diode unit 110 and the mesa of the electrode unit 120 are connected into a continuous layer.

In this embodiment, a passivation layer 160 is further provided to cover a surface of each of the light-emitting diode unit 110 and the electrode unit 120. A material of the passivation layer 160 may be Al₂O₃ or SiO₂. The passivation layer 160 can provide isolation by covering the light-emitting diode unit 110 and the electrode unit 120, thereby protecting the light-emitting diode unit 110 and the electrode unit 120.

In some embodiments, a filling structure 170 is formed in the first opening 150 and configured to cover a part of the conductive layer 200 located in the first opening 150.

It can be understood that the filling structure 170 can protect the conductive layer 200 and make the light-emitting array substrate flatter, facilitating subsequent processing.

In some embodiments, the filling structure 170 is made of a metallic material.

It can be understood that the filling structure 170 made of the metallic material is electrically conductive, which can improve conductivity at the electrode unit 120. In addition, a part of the conductive layer 200 extending from an outside to an inside of the first opening 150 has a bend, and the filling structure 170 can further prevent breakage at the bend of the conductive layer 200.

In some other embodiments, the filling structure 170 may also be made of a material such as SiO₂, PI (polyimide), photoresist, BCB (benzocyclobutene), or a dam adhesive. The above materials are commonly used for fabricating the filling structure. A planarization layer 180 is further provided between the light-emitting diode unit 110 and the electrode unit 120. The planarization layer 180 may be made of a material such as SiO₂, PI, photoresist, BCB, or a dam adhesive, and is configured to support the light-emitting diode unit 110 and the electrode unit 120.

With continued reference to FIG. 4, in some embodiments, the first opening 150 is formed in a connection region 190 between the electrode unit 120 and the light-emitting diode unit 110 adjacent to the electrode unit 120, and the second conductivity-type electrode 140 of the electrode unit 120 includes an extending portion 141 extending to the connection region 190 along a side wall of the electrode unit 120. The first opening 150 is configured to expose the extending portion 141 toward the side where the conductive layer 200 is located.

In this embodiment, the light-emitting array substrate differs from that shown in FIG. 3 in that the first opening 150 is located outside the electrode unit 120.

The electrode unit 120 and the light-emitting diode unit 110 have the same mesa, which includes the P-type semiconductor layers, the active layer, and the N-type semiconductor layer that are stacked, as can be seen in the foregoing embodiments. Similarly, the light-emitting array substrate provided in this embodiment also has other structures that are the same as those of the light-emitting array substrate in the aforementioned embodiments, and description of these same structures may also refer to the aforementioned embodiments.

It can be understood that the second conductivity-type electrode 140 of the electrode unit 120 is connected to the conductive layer 200 passing through the first opening 150. However, since the semiconductor stacked structure is equivalent to a PN junction, an actual current may flow to the conductive layer 200 through the second conductivity-type electrode 140 of the electrode unit 120.

It can be understood that the first conductivity-type electrode 130 of the light-emitting diode unit 110 may be formed by directly depositting on the light-emitting diode unit 110, and the second conductivity-type electrode 140 of the electrode unit 120 may be formed by directly depositting on the electrode unit 120. Thus, the second conductivity-type electrode 140 of the electrode unit 120 can extend to the connection region 190 between the electrode unit 120 and the light-emitting diode unit 110 along the side wall of the electrode unit 120.

In some embodiments, the light-emitting array substrate includes a plurality of light-emitting diode units 110, and a conductive layer 200 is in contact with a second conductivity-type electrode 140 corresponding to each of the plurality of light-emitting diode units 110.

In this embodiment, the second conductivity-type electrode 140 of each of the plurality of light-emitting diode units 110 is connected to the first side through the conductive channel at the electrode unit 120. The second conductivity-type electrode 140 may be an N-type electrode, and the light-emitting array substrate adopts a common N-electrode electrical connection. Alternatively, the second conductivity-type electrode 140 may be a P-type electrode, and the light-emitting array substrate adopts a common P-type electrode connection.

In some other embodiments, the plurality of light-emitting diode units 110 may be divided into a plurality of groups, and the second conductivity-type electrodes 140 corresponding to each of the plurality of groups of light-emitting diode units 110 are connected to a same conductive layer 200. The conductive layers 200 corresponding to each of the plurality of groups of light-emitting diode units 110 are discontinuous with respect to one another.

In some embodiments, the light-emitting array substrate includes a plurality of electrode units 120, and the conductive layer 200 is in contact with an extending portion 141 corresponding to each of the plurality of electrode units 120.

In this embodiment, the plurality of electrode units 120 are provided and may be arranged at an edge or a middle part of the light-emitting array substrate, which is not limited in this embodiment. Since the second conductivity-type electrodes 140 of the plurality of electrode units 120 are connected to the same conductive layer 200, by increasing the number of electrode units 120, a current of the second conductivity-type electrode 140 of the light-emitting diode unit 110 of the light-emitting array substrate is shared, thereby reducing voltage stress at the electrode unit 120.

In some other embodiments, the plurality of electrode units 120 may be divided into a plurality of groups, and the second conductivity-type electrodes 140 corresponding to each of the plurality of groups of electrode units 120 are connected to a same conductive layer 200. The conductive layers 200 corresponding to each of the plurality of groups of electrode units 120 are discontinuous with respect to one another.

In some embodiments, the light-emitting array substrate includes a plurality of light-emitting diode units 110, and the second conductivity-type electrode 140 of the electrode unit 120 is connected to the second conductivity-type electrode 140 of each of the plurality of light-emitting diode units 110, to form a common second conductivity-type conductive channel.

Referring to FIGS. 5 and 6, an embodiment of the present disclosure also provides a light-emitting array chip. The light-emitting array chip includes a drive backplane 300 and the light-emitting array substrate according to the aforementioned embodiments. The light-emitting array substrate is bonded to the drive backplane.

The light-emitting array chip shown in FIG. 5 is formed by bonding the light-emitting array substrate shown in FIG. 3 to the drive backplane. The light-emitting array chip shown in FIG. 6 is formed by bonding the light-emitting array substrate shown in FIG. 4 to the drive backplane.

In some embodiments, the drive backplane 300 may be a complementary metal-oxide-semiconductor (CMOS) backplane or a thin-film transistor (TFT) backplane. The bonding connection may employ either hybrid bonding or eutectic bonding.

In some embodiments, the first conductivity-type electrode 130 of the light-emitting diode unit 110 and the second conductivity-type electrode 140 of the electrode unit 120 of the light-emitting array substrate are further connected to a conductive connector 400. The conductive connector 400 is configured for the bonding connection. The conductive connector 400 may be made of a metallic material, such as tin, gold, nickel, palladium, copper, or an alloy including at least two of tin, gold, nickel, palladium, or copper, for example, a gold-tin alloy.

It can be understood that a drive current on the drive backplane 300 flows into the light-emitting diode unit 110 from the first conductivity-type electrode 130 of the light-emitting diode unit 110, then flows out of the second conductivity-type electrode 140 of the light-emitting diode unit 110, then flows to the second conductivity-type electrode 140 of the electrode unit 120 through the conductive layer 200, and finally returns to the drive backplane 300.

Referring to FIG. 7, an embodiment of the present disclosure also provides a method for manufacturing a light-emitting array substrate. In this embodiment, the method for manufacturing the light-emitting array substrate includes the following steps.

In step 11, a substrate 500 is provided, and a light-emitting epitaxial layer 600 is formed on the substrate. The light-emitting epitaxial layer 600 has a first side and a second side opposite to the first side, and the second side is a side where the substrate 500 is located.

In step 12, the light-emitting epitaxial layer 600 is etched at its first side to form a light-emitting diode unit 110 and an electrode unit 120.

In step 13, on the first side, a first conductivity-type electrode 130 is formed on the light-emitting diode unit 110, and a second conductivity-type electrode 140 is formed on the electrode unit 120.

In step 14, the substrate 500 is removed.

In step 15, a first opening 150 is formed on the light-emitting epitaxial layer 600. The first opening 150 is configured to expose the second conductivity-type electrode 140 of the electrode unit 120 toward the second side of the light-emitting epitaxial layer 600.

In step 16, on the second side, a second conductivity-type electrode 140 is formed on the light-emitting diode 110 unit.

In step 17, a conductive layer 200 is formed on the second side. The conductive layer 200 is contact-connected to the second conductivity-type electrode 140 of the light-emitting diode unit 110 and to the second conductivity-type electrode 140 of the electrode unit 120 that is exposed through the first opening 150.

Referring to FIG. 8, the substrate 500 may be made of a semiconductor material, such as silicon or gallium arsenide, or of a non-conductive material, such as sapphire or glass. The light-emitting epitaxial layer 600 includes a first doped semiconductor 610, a second doped semiconductor 630, and an active layer 620.

In some embodiments, the first doped semiconductor 610 is a P-type semiconductor, and the second doped semiconductor 630 is an N-type semiconductor. Alternatively, the first doped semiconductor 610 is an N-type semiconductor, and the second doped semiconductor 630 is a P-type semiconductor. The P-type semiconductor may be P-type gallium nitride, and the N-type semiconductor may be N-type gallium nitride.

Referring to FIG. 9, the first doped semiconductor 610, the active layer 620 and second doped semiconductor 630 are partially removed by etching to expose the second doped semiconductor 630, forming a functionalized stepped structure (that is, a mesa structure, or a mesa) that serves as the light-emitting diode unit 110 and the electrode unit 120. An etching depth is determined by a predetermined thickness that the second doped semiconductor 630 can reach, and the retained second doped semiconductor 630 is continuous in a horizontal direction.

In some embodiments, the second doped semiconductor 630 may be etched through to form the light-emitting diode unit 110 and the electrode unit 120 that are independent of each other.

It should be noted that subsequent to etching the light-emitting epitaxial layer 600 in step 12, a plurality of stepped structures are formed, and each of the plurality of stepped structures may have a same shape. A part of the plurality of stepped structures serves as the light-emitting diode unit 110, and the other part of the plurality of stepped structures serves as the electrode unit 120. In practice, the electrode unit 120 is obtained by reusing a part of the stepped structures that has light emission capability. The specific positions of the light-emitting diode unit 110 and the electrode unit 120 may be selected as required.

The first conductivity-type electrode 130 of the light-emitting diode unit 110 and the second conductivity-type electrode 140 of the electrode unit 120 may be formed through metal evaporation, metal sputtering, electron beam evaporation, metal lift-off technology (Lift-Off), etc. The material type of each of the first conductivity-type electrode 130 of the light-emitting diode unit 110 and the second conductivity-type electrode 140 of the electrode unit 120 is the same as a conductivity type of the first doped semiconductor 610. For example, when the first doped semiconductor 610 is P-type, the first conductivity-type electrode 130 of the light-emitting diode unit 110 and the second conductivity-type electrode 140 of the electrode unit 120 are P-type; and when the first doped semiconductor 610 is N-type, the first conductivity-type electrode 130 of the light-emitting diode unit 110 and the second conductivity-type electrode 140 of the electrode unit 120 are N-type. The first conductivity-type electrode 130 of the light-emitting diode unit 110 and the second conductivity-type electrode 140 of the electrode unit 120 may be made of tin, gold, nickel, palladium, copper, or an alloy including at least two of tin, gold, nickel, palladium, or copper. For example, the alloy may be a gold-nickel alloy or a copper-nickel alloy.

In this embodiment, step 13 may include: forming a passivation layer 160 on an upper surface of each of the light-emitting diode unit 110 and the electrode unit 120; etching a part of the passivation layer 160 on a top of each of the light-emitting diode unit 110 and the electrode unit 120 to form a second opening configured to expose the light-emitting diode unit 110 and a second opening configured to expose the electrode unit 120; and simultaneously forming, using a same photolithography process, the first conductivity-type electrode 130 in the second opening of the light-emitting diode unit 110 and the second conductivity-type electrode 140 in the second opening of the electrode unit 120.

Referring to FIG. 10, subsequent to the completion of the etching, the passivation layer 160 may be prepared by an atomic layer deposition (ALD) process. The passivation layer 160 may be made of Al₂O₃, SiO₂, or other suitable materials. The passivation layer 160 can provide insulation protection for the upper surface of each of the light-emitting diode unit 110 and the electrode unit 120.

Referring to FIG. 11, a patterned mask design is performed on the passivation layer 160 on the upper surface of each of the light-emitting diode unit 110 and the electrode unit 120 to remove the part of the passivation layer 160 to expose the first doped semiconductor 610. Then, the first conductivity-type electrode 130 is formed on the exposed first doped semiconductor 610 of the light-emitting diode unit 110, and the second conductivity-type electrode 140 is formed on the exposed first doped semiconductor 610 of the electrode unit 120.

The second conductivity-type electrode 140 formed on the electrode unit 120 still uses a material with the same conductivity type as that of the first doped semiconductor 610 and is completed using the same photolithography process to simplify the process. Since the second conductivity-type electrode 140 is connected to the second conductivity-type electrode 140 of the light-emitting diode unit 110 through the conductive layer 200, using the different polarity materials to achieve the electrode connection does not affect the conductivity therebetween.

It should be noted that the structural diagram shown in FIG. 11 is a schematic diagram of a stage in a manufacturing process of the light-emitting array substrate shown in FIG. 3. In this example, the second conductivity-type electrode 140 of the electrode unit 120 is located on the top of the electrode unit 120.

It can be understood that removing the substrate 500 can facilitate processing on the other side of each of the light-emitting diode unit 110 and the electrode unit 120. The substrate 500 may be removed by means including, but not limited to, laser lift-off, dry etching, wet etching, and mechanical polishing.

In some embodiments, the method may further include, prior to step 14: forming a planarization layer 180 on the first side of the light-emitting epitaxial layer 600, in which the planarization layer 180 is configured to cover the light-emitting diode unit 110 and the electrode unit 120; etching a part of the planarization layer 180 above the first conductivity-type electrode 130 of the light-emitting diode unit 110 and the second conductivity-type electrode 140 of the electrode unit 120 to form third openings configured to expose the first conductivity-type electrode 130, and the second conductivity-type electrode 140 of the electrode unit 120; forming conductive connectors 190 in the third openings; and bonding the conductive connectors 190 to the drive backplane 300.

Referring to FIG. 12, the planarization layer 180 is formed by filling with a planarization material, making a position above the light-emitting diode unit 110 and the electrode unit 120 flat. The planarization layer 180 may be made of SiO₂, PI, photoresist, BCB, a dam adhesive, or other suitable materials.

In some embodiments, when the planarization layer 180 is made of SiO₂, it may be prepared using a plasma-enhanced chemical vapor deposition (PECVD) process. When the planarization layer 180 is made of photoresist, it may be prepared using a spin-coating process.

Referring to FIG. 13, by performing a patterned mask design on the planarization layer 180, a part of the planarization layer 180 above the first conductivity-type electrode 130 of the light-emitting diode unit 110 and the second conductivity-type electrode 140 of the electrode unit 120 is removed to expose the first conductivity-type electrode 130, and the second conductivity-type electrode 140 of the electrode unit 120. Then, the conductive connector 400 is formed through a process such as lift-off, and is configured for bonding to the drive backplane 300.

In some embodiments, the conductive connector is made of tin, gold, nickel, palladium, copper, or an alloy including at least two of tin, gold, nickel, palladium, or copper, such as a gold-tin alloy.

Referring to FIG. 14, the structure in FIG. 13 is bonded to the drive backplane 300. The drive backplane 300 may be a complementary metal-oxide-semiconductor (CMOS) backplane or a thin-film transistor (TFT) backplane. The bonding connection may employ either hybrid bonding or eutectic bonding.

Referring to FIG. 15, subsequent to the removal of the substrate 500, the second doped semiconductor 630 may be thinned. The thinning operation may include dry etching, wet etching, or mechanical polishing, etc. The second doped semiconductor 630 is thinned to expose the passivation layer 160.

In some embodiments, when thinning the second doped semiconductor 630, the continuous second doped semiconductor 630 of a certain thickness may be retained, that is, the second doped semiconductor 630 of a certain thickness may be retained above the passivation layer 160, so that the passivation layer 160 may not be exposed. In the the passivation layer 160 is not exposed, the part of a mesa of the light-emitting diode unit 110 close to the second side is connected to the part of a mesa of the electrode unit 120 close to the second side. Alternatively, when thinning the second doped semiconductor 630, the passivation layer 160 is exposed on the second side of the thinned light-emitting epitaxial layer 600.

Referring to FIG. 16, in this embodiment, the step of forming the first opening 150 in the light-emitting epitaxial layer 600 includes: etching the electrode unit 120 on the second side of the light-emitting epitaxial layer 600 to form a first opening 150 configured to expose the second conductivity-type electrode 140 of the electrode unit 120.

In this embodiment, by etching the electrode unit 120, the second doped semiconductor 630, the active layer 620, and the first doped semiconductor 610 are partially removed sequentially to form the first opening 150. The second conductivity-type electrode 140 of the electrode unit 120 is exposed through the first opening 150.

In some embodiments, the second doped semiconductor 630, the active layer 620, and the first doped semiconductor 610 within the electrode unit 120 may be completely removed.

In some embodiments, the method may further include, subsequent to the forming the first opening in the light-emitting epitaxial layer 600: forming, on the second side, a second conductivity-type electrode 140 on the light-emitting diode unit 110.

The second conductivity-type electrode 140 forms an ohmic contact with a second electrode of the light-emitting diode unit 110 for an electrical connection with a drive circuit to more easily control the outflowing current.

Referring to FIG. 17, the second conductivity-type electrode 140 may be prepared using a Lift-Off process. The second conductivity-type electrode 140 may include a plurality of protrusions formed on a side of the light-emitting diode unit 110 opposite to the first conductivity-type electrode 130 to form an ohmic contact. A material of the second conductivity-type electrode 140 may be Ti/Al or Ti/Au.

Referring to FIG. 18, due to the presence of the first opening 150, the conductive layer 200 is deposited into a bottom of the first opening 150 during formation of the conductive layer 200 and is in contact with the second conductivity-type electrode 140 of the electrode unit 120 exposed in the opening 150 to form the conductive channel extending through the light-emitting epitaxial layer 600.

It can be understood that a drive current on the drive backplane 300 flows into the light-emitting diode unit 110 from the first conductivity-type electrode 130 of the light-emitting diode unit 110, then flows out of the second conductivity-type electrode 140 of the light-emitting diode unit 110, then flows to the second conductivity-type electrode 140 of the electrode unit 120 through the conductive layer 200, and finally returns to the drive backplane 300.

The conductive layer 200 is formed on the second side of the electrode unit 120 and the second side of the light-emitting diode unit 110. The conductive layer 200 may be made of an Indium tin oxide (ITO) semiconductor transparent conductive film.

In some embodiments, after the conductive layer 200 is formed, a cavity within the opening 150 is filled with the planarization material to realize planarization. The planarization material is the same as the material of the planarization layer 180.

In some other embodiments, the cavity within the opening 151 may also be filled with a metallic material to improve conductivity at the electrode unit 120 and prevent breakage at a bend of a side wall.

Referring to FIGS. 19 to 21, another embodiment of the present disclosure provides schematic diagrams of some stages of a manufacturing process of a light-emitting array substrate shown in FIG. 4.

As shown in FIG. 19, in this embodiment, the second conductivity-type electrode 140 of the electrode unit 120 extends to the bottom of the electrode unit 120 from the top of the electrode unit 120 along the side wall of the electrode unit 120, and extends to the connection region 190 between the electrode unit 120 and the light-emitting diode unit 110 adjacent to the electrode unit 120, and the second conductivity-type electrode 140 of the electrode unit 120 has an extending portion 141 within the connection region 190.

Different from the manufacturing method provided in the aforementioned embodiments, the second conductivity-type electrode 140 of the electrode unit 120 in this embodiment also extends to the connection region 190 between the electrode unit 120 and the light-emitting diode unit 110. The manufacturing process prior to the structure shown in FIG. 19 may be referred to FIGS. 8 to 10.

In this embodiment, the second conductivity-type electrode 140 of the electrode unit 120 may be formed by processes such as metal evaporation, metal sputtering, electron beam evaporation, and metal lift-off technology (Lift-Off). During patterning, by designing a pattern, the part of the second conductivity-type electrode 140 of the electrode unit 120 between the electrode unit 120 and the light-emitting diode unit 110 is retained to form the extending portion 141. The extending portion 141 includes a first portion extending to the second side of the electrode unit 120 from the first side of the electrode unit 120 along the side wall of the electrode unit 120 and a second portion extending on the second side of the electrode unit 120 towards the light-emitting diode unit 110.

In this embodiment, the second conductivity-type electrode 140 formed on the electrode unit 120 is also made of a material with the same conductivity type as that of the first doped semiconductor 610, and the second conductivity-type electrode 140 of the electrode unit 120 and the first doped semiconductor 610 are completed using the same photolithography process to simplify the process. Since the second conductivity-type electrode 140 of the electrode unit 120 is connected to an N-type electrode of the light-emitting diode unit 110 through the conductive layer 200, using different polarity materials to achieve the electrode connection does not affect its conductivity. The semiconductor stacked structure within the electrode unit 120 is equivalent to a PN junction, and an actual current may flow to the conductive layer 200 through the second conductivity-type electrode 140 of the electrode unit 120.

Referring to FIG. 20, in this embodiment, the step of forming the first opening 150 on the light-emitting epitaxial layer 600 includes: etching, on the second side of the light-emitting epitaxial layer 600, the connection region 190 to form the first opening 150 configured to expose the second conductivity-type electrode 140 of the electrode unit 120.

In this embodiment, the first opening 150 is formed in the connection region 190 between the light-emitting diode unit 110 and the electrode unit 120. When thinning the second doped semiconductor 630, if the second doped semiconductor 630 is thinned to expose the passivation layer 160, only a part of the passivation layer 160 needs to be removed when forming the first opening 150. If the second doped semiconductor 630 of a certain thickness is retained above the passivation layer 160 when thinning the second doped semiconductor 630, only portions of the second doped semiconductor 630 and the passivation layer 160 need to be removed sequentially when forming the first opening 150.

Referring to FIG. 21, due to the presence of the first opening 150, the conductive layer 200 is deposited into the bottom of the first opening 150 during formation of the conductive layer 200, thereby contacting the extending portion 141 exposed within the first opening 150 to form the conductive channel extending through the light-emitting epitaxial layer 600.

Although embodiments of the present disclosure have been illustrated and described, it is conceivable for those of ordinary skill in the art that various changes, modifications, replacements, and variations can be made to these embodiments without departing from the principles and spirit of the present disclosure. The scope of the present disclosure shall be defined by the claims as appended and their equivalents.

What is claimed is:

1. A light-emitting array substrate, comprising:
a light-emitting diode unit provided with a first conductivity-type electrode on a first side of the light-emitting diode unit and a second conductivity-type electrode on a second side of the light-emitting diode unit, the first conductivity-type electrode and the second conductivity-type electrode having an independent potential connection relationship; and
an electrode unit provided with a second conductivity-type electrode on a first side of the electrode unit, the first side of the light-emitting diode unit and the first side of the electrode unit being on a same side,
wherein the second conductivity-type electrode of the electrode unit is connected to the second conductivity-type electrode on the second side of the light-emitting diode unit to form a second conductivity-type conductive channel.

2. The light-emitting array substrate according to claim 1, wherein the second conductivity-type electrode of the electrode unit and the first conductivity-type electrode of the light-emitting diode unit are manufactured using a same process.

3. The light-emitting array substrate according to claim 2, wherein:
each of the second conductivity-type electrode of the electrode unit and the first conductivity-type electrode of the light-emitting diode unit is made of tin, gold, nickel, palladium, copper or an alloy comprising at least two of tin, gold, nickel, palladium, or copper; and
the second conductivity-type electrode of the light-emitting diode unit is made of Ti/Al or Ti/Au.

4. The light-emitting array substrate according to claim 1, wherein a mesa of the electrode unit and a mesa of the light-emitting diode unit are at least partially formed using a same process.

5. The light-emitting array substrate according to claim 4, further comprising a conductive layer disposed on the second side of the light-emitting diode unit, the conductive layer being connected to the second conductivity-type electrode of the light-emitting diode unit and the second conductivity-type electrode of the electrode unit to form the conductive channel.

6. The light-emitting array substrate according to claim 5, wherein the electrode unit has an opening extending through the mesa of the electrode unit, the opening being configured to expose the second conductivity-type electrode of the electrode unit toward a side where the conductive layer is located, and the conductive layer being connected to the second conductivity-type electrode of the electrode unit through the opening.

7. The light-emitting array substrate according to claim 6, wherein a filling structure is formed in the opening and configured to cover a part of the conductive layer located in the opening and to achieve planarization.

8. The light-emitting array substrate according to claim 7, wherein the fillingstructure is made of a metallic material.

9. The light-emitting array substrate according to claim 5, wherein a connection region between the light-emitting diode unit and the electrode unit has an opening, and the second conductivity-type electrode of the electrode unit extends to the connection region along an outer side wall of the mesa of the electrode unit and is exposed through the opening.

10. The light-emitting array substrate according to claim 1, wherein a part of a mesa of the light-emitting diode unit close to the second side is connected to a part of a mesa of the electrode unit close to the second side.

11. The light-emitting array substrate according to claim 1, further comprising a plurality of said light-emitting diode units, and a conductive layer is in contact with a second conductivity-type electrode corresponding to each of the light-emitting diode units.

12. The light-emitting array substrate according to claim 11, further comprising a plurality of said electrode units, and the conductive layer is in contact with a second conductivity-type electrode corresponding to each of the electrode units.

13. The light-emitting array substrate according to claim 1, further comprising a plurality of said light-emitting diode units, and the second conductivity-type electrode of the electrode unit is connected to the second conductivity-type electrode of each of the plurality of said light-emitting diode units, to form a common second conductivity-type conductive channel.

14. A light-emitting array chip, comprising:
a drive backplane; and
a light-emitting array substrate, wherein the light-emitting array substrate is bonded to the drive backplane,
wherein the light-emitting array substrate comprises:
a light-emitting diode unit provided with a first conductivity-type electrode on a first side of the light-emitting diode unit and a second conductivity-type electrode on a second side of the light-emitting diode unit, the first conductivity-type electrode and the second conductivity-type electrode having an independent potential connection relationship; and
an electrode unit provided with a second conductivity-type electrode on a first side of the electrode unit, the first side of the light-emitting diode unit and the first side of the electrode unit being on a same side,
wherein the second conductivity-type electrode of the electrode unit is connected to the second conductivity-type electrode on the second side of the light-emitting diode unit to form a second conductivity-type conductive channel.

15. A method for manufacturing a light-emitting array substrate, the method comprising:
providing a substrate, and forming a light-emitting epitaxial layer on the substrate, wherein the light-emitting epitaxial layer has a first side and a second side opposite to the first side, and the second side is a side where the substrate is located;
etching the light-emitting epitaxial layer at the first side to form a light-emitting diode unit and an electrode unit;
forming, on the first side, a first conductivity-type electrode on the light-emitting diode unit and a second conductivity-type electrode on the electrode unit;
removing the substrate;
forming a first opening on the light-emitting epitaxial layer, the first opening being configured to expose the second conductivity-type electrode of the electrode unit toward the second side of the light-emitting epitaxial layer;
forming, on the second side, a second conductivity-type electrode on the light-emitting diode unit; and
forming a conductive layer on the second side, the conductive layer being contact-connected to the second conductivity-type electrode of the light-emitting diode unit and to the second conductivity-type electrode of the electrode unit that is exposed through the first opening.

16. The method according to claim 15, wherein said forming the first conductivity-type electrode on the light-emitting diode unit and the second conductivity-type electrode on the electrode unit comprises:
forming a passivation layer on an upper surface of each of the light-emitting diode unit and the electrode unit;
etching a part of the passivation layer on a top of each of the light-emitting diode unit and the electrode unit to form a second opening configured to expose the light-emitting diode unit and a second opening configured to expose the electrode unit; and
simultaneously forming, using a same photolithography process, the first conductivity-type electrode in the second opening of the light-emitting diode unit and the second conductivity-type electrode in the second opening of the electrode unit.

17. The method according to claim 16, wherein:
the second conductivity-type electrode of the electrode unit is located at the top of the electrode unit; and
said forming the first opening on the light-emitting epitaxial layer comprises:
etching, on the second side of the light-emitting epitaxial layer, the electrode unit to form the first opening configured to expose the second conductivity-type electrode of the electrode unit.

18. The method according to claim 16, wherein:
the second conductivity-type electrode of the electrode unit extends to a bottom of the electrode unit from the top of the electrode unit along a side wall of the electrode unit, and extends to a connection region between the electrode unit and the light-emitting diode unit adjacent to the electrode unit; and
said forming the first opening on the light-emitting epitaxial layer comprises:
etching, on the second side of the light-emitting epitaxial layer, the connection region to form the first opening configured to expose the second conductivity-type electrode of the electrode unit.

19. The method according to claim 15, further comprising, prior to said removing the substrate:
forming a planarization layer on the first side of the light-emitting epitaxial layer, the planarization layer being configured to cover the light-emitting diode unit and the electrode unit;
etching a part of the planarization layer above the first conductivity-type electrode of the light-emitting diode unit and the second conductivity-type electrode of the electrode unit to form third openings configured to expose the first conductivity-type electrode, and the second conductivity-type electrode of the electrode unit;
forming conductive connectors in the third openings; and
bonding the conductive connectors to a drive backplane,
wherein the conductive connectors are made of tin, gold, nickel, palladium, copper, or an alloy comprising at least two of tin, gold, nickel, palladium, or copper.

20. The method according to claim 19, further comprising, subsequent to said removing the substrate:
thinning the light-emitting epitaxial layer at the second side,
wherein a passivation layer is formed on a surface of each of the light-emitting diode unit and the electrode unit on the first side and exposed on the second side of the thinned light-emitting epitaxial layer.
